(19) United States
(12) Patent Application Publication
(10) Pub. No.: US 2016/0139807 A1
(43) Pub. Date: May 19, 2016

(54) WRITE FLOW CONTROL FOR MEMORY MODULES THAT INCLUDE OR INTERFACE WITH NON-COMPLIANT MEMORY TECHNOLOGIES

(71) Applicant: HEWLETT-PACKARD DEVELOPMENT COMPANY, L.P., Houston, TX (US)

(72) Inventors: Gregg B. LESARTRE, Fort Collins, CO (US); Andrew R. WHEELER, Fort Collins, CO (US)

(73) Assignee: Hewlett-Packard Development Company, L.P., Houston, TX (US)

(21) Appl. No.: 14/897,536

(22) PCT Filed: Jul. 9, 2013
(86) PCT No.: PCT/US2013/049654

§ 371 Date: Dec. 10, 2015

(51) Int. Cl. G06F 3/06; G11C 7/10

(52) U.S. Cl. CPC G06F 3/061; G06F 3/0688; G06F 3/0659; G11C 7/1072

(57) ABSTRACT

Example embodiments relate to write flow control for memory modules that include or interface with non-compliant memory technologies. A memory module may include an interface to a memory bus and a memory controller that comply with a data transfer standard. The memory module may include a write buffer to receive write commands from the interface to the memory bus. The write buffer may cause the write commands to be transmitted to the non-compliant memory technology using a communication protocol that does not comply with the data transfer standard. The memory module may include a flow control credit counter to monitor the capacity of the write buffer, and to provide a credit count to the memory controller that indicates the number of write commands that the write buffer can accept.

### BACKGROUND

Dynamic random-access memory (DRAM) is a type of volatile memory that stores bits of data in capacitors that require power in order to hold the values of the bits. Because power is required to hold the values, DRAM is referred to as a volatile or dynamic memory, as opposed to static memory. Various modern computing systems utilize DRAM DIMMs to implement system memory. A DIMM (dual in-line memory module) is a computer memory component or module that includes a number of DRAM memory circuits. A DIMM may be a printed circuit board and may include DRAM memory circuits mounted thereon. A DIMM may plug into or connect with a motherboard of a computing system to interface with a memory bus, which may in turn interface with a memory controller.

### BRIEF DESCRIPTION OF THE DRAWINGS

The following detailed description references the drawings, wherein:

FIG. 1A is a block diagram of an example computing system that implements write flow control for memory modules that include or interface with non-compliant memory technologies;

FIG. 1B is a block diagram of an example computing system that implements write flow control for memory modules that include or interface with non-compliant memory technologies;

FIG. 2A is a flowchart of an example method for write flow control for memory modules that include or interface with non-compliant memory technologies;

FIG. 2B is a flowchart of an example method for write flow control for memory modules that include or interface with non-compliant memory technologies;

FIG. 3 is a block diagram of an example computing system for write flow control for memory modules that include or interface with non-compliant memory technologies; and

FIG. 4 is a flowchart of an example method for write flow control for memory modules that include or interface with non-compliant memory technologies.

### DETAILED DESCRIPTION

Various DIMMs may comply with the double data rate (DDR) data transfer standard. In such a scenario, in order for the memory controller and the memory bus to communicate with a DDR-compliant DIMM, the memory controller and memory bus may be required to be DDR-compliant as well. Thus in various computing systems, the memory controller and the memory bus are designed to operate according to the DDR data rate transfer standard (i.e., they are DDR compliant). In computing systems that include a DDR compliant memory controller, various other components of the computing system (e.g., central processor, motherboard, etc.) may be designed to interface with the DDR compliant memory controller. Furthermore, DDR compliant memory controllers, because they are designed to interface with a DDR compliant memory bus and DDR compliant DIMMs, may be designed to expect certain memory communication characteristics. For example, when the memory controller issues a write command (simply referred to as a “write”) to a DIMM, the memory controller may expect the write to be completed within a defined (e.g., short) period of time. Specifically, the DDR specification may require that a memory controller be able to feed write commands to the DIMM at a predictable, defined and relatively fast rate. In other words, the DDR standard is referred to as a deterministic protocol, meaning that when commands are sent from the memory controller to the memory bus, it is expected that the commands will complete in a certain number of cycles. DDR DRAM memory circuits are able to complete writes issued to them within such a predictable, defined and relatively fast rate, but other types of memory circuits/technologies may not.

In some scenarios, it may be desirable to implement non-volatile memory technologies (e.g., FLASH, spinning disk hard drive, etc.) that interface with a DDR compliant memory bus and memory controller (e.g., via a DIMM or similar memory module). Various non-volatile memory technologies may be unable to ensure that writes issued to them will be completed within a predictable, defined and/or relatively fast rate. For example, non-volatile memory technologies, instead of completing writes at a defined rate, may indicate (e.g., via a wire, line or signal) when a write has been completed. Because these various non-volatile memory technologies may not behave as may be expected by a DDR-compliant memory controller, such a memory controller may be unable to communicate with such memory technologies.

Some approaches to handing non-volatile memory technologies may include adding an extra wire or line such that a DIMM may signal when the DIMM (e.g., non-volatile memory technology) is not ready to accept another write. Such an approach may require modification to several components of the computing system, however. For example, the motherboard, memory bus, and memory controller may need to be modified to run an extra line/wire for such a signal. Furthermore, the memory controller may need to be modified to understand how to handle/support the extra line/wire and signal. In other words, a non-compliant (e.g., non-DDR compliant) motherboard, memory bus and memory controller, at least, may be required for such an approach. This may require a system administrator to expend significant costs to replace various components of a computing system.

Other approaches to handling non-volatile memory technologies may include connecting these technologies elsewhere in the computing system (e.g., not on or via a memory module such as a DIMM). In such a scenario, in order for the memory controller (and perhaps a processor) to read data from these non-volatile memory technologies, the data may first be required to be explicitly moved to the DIMM (e.g., DRAM memory circuits on the DIMM) before the memory controller and/or processor can access the data. Such a preliminary explicit transfer of data may be time consuming, among other potential problems.

The present disclosure describes write flow control for memory modules that include or interface with non-compliant memory technologies. The present disclosure describes a flow control module that allows non-compliant (e.g., non-volatile) memory technologies to interface with a compliant (e.g., DDR compliant) memory bus and a compliant (e.g., DDR compliant) memory controller. This may allow the non-volatile memory technologies to take advantage of benefits (e.g., performance benefits) of communicating with the memory controller. The present disclosure describes sending credits or a credit count to the memory controller that may cause the memory controller to refrain from sending write commands to avoid overwhelming various memory circuits/technologies beyond their ability to complete writes. The present disclosure describes a flow control module between the memory controller (e.g., a modified but still compliant memory controller) and at least one non-compliant memory circuit/technology. The flow control module may buffer, track and manage write commands, and may signal (e.g., via flow control credits) to the memory controller when the memory controller may issue write commands. When the memory controller does issue write commands, it may send them in a manner that complies with a particular data transfer standard (e.g., DDR); however, the memory controller may refrain from sending writes if various memory circuits/technologies are unable to keep up. For example, by not overwhelming slower non-volatile memory technologies, these technologies may have sufficient time to complete the write commands.

The present disclosure may also offer benefits over some approaches that include adding an extra wire or line such that a DIMM may signal when the DIMM is not ready to accept another write. The present disclosure describes a solution where flow control credits or credit counts may be requested, read or sent via compliant (e.g., DDR compliant) interfaces and wiring paths. For example, a register may hold an updated flown control credit count and the memory controller may read it by issuing a read command to an address associated with the register. In this respect, the present disclosure may allow high capacity, lower-cost, non-volatile memories to interface with the memory controller, which may allow such memories to operate alongside conventional memories (e.g., DDR DRAM memories) in a computing system. Additionally, a compliant (e.g., DDR compliant) memory controller may communicate with memory circuits/technologies that have unknown or uncertain write latencies.

Throughout this disclosure, the term “compliant” (e.g., as in compliant memory technology or compliant memory controller) may refer to a computer component that is designed to comply with a particular data transfer standard (e.g., DDR or other data transfer standard). Likewise, the term “non-compliant” may refer to a computer component that is not designed to comply with (or is incompatible with) the particular data transfer standard. The term “data transfer standard” may refer to a protocol by which data is transferred over a number of communication wires or lines (e.g., metal wires over which information is sent and/or received). The data transfer standard may specify a number of data transfer cycles, timing of various commands (e.g., reads, writes, etc.), and various other details that may be required for one computer component to send and/or receive data from another computer component. As one specific example, if the data transfer standard is DDR, then a computer component may be a compliant (e.g., DDR compliant) computer component or a non-compliant computer component (e.g., non-DDR compliant) with respect to the DDR data transfer standard. In the case of DDR, some non-volatile memory circuits or technologies are examples of non-compliant computer components, for example, because they do not operate like volatile DDR memory circuits. Thus, in various descriptions below, when reference is made to a non-volatile memory circuit or technology, it may be inferred it is a non-compliant computer component. Examples of non-volatile memory technologies (e.g., that are non-DDR compliant) may include PCRAM, SATA, STT-RAM, reRAM, memristor, FLASH and spinning disk on PCIe. The present disclosure may apply to various other types of non-volatile memory technologies as well. Throughout this disclosure, the term “command” (e.g., as in a write command or read command) may refer to a multi-bit digital value, where each bit may be sent over a dedicated communication wire or line. A command may have multiple “fields” where each field is a multi-bit digital value. Example fields may be “address” (addr), “command” (cmd) and “data.” The command field (i.e., cmd) should not be confused with the broader command (e.g., write or read command). The cmd field may indicate what type of command is intended by the broader command, and the broader command may include additional information required to execute the command (e.g., addr and data).

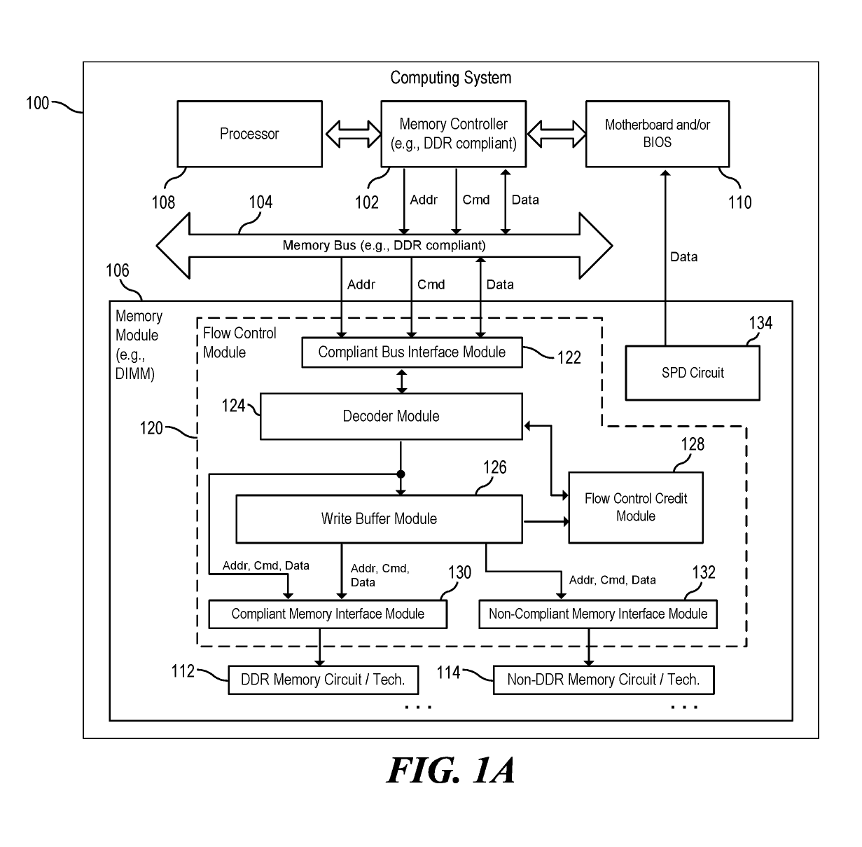

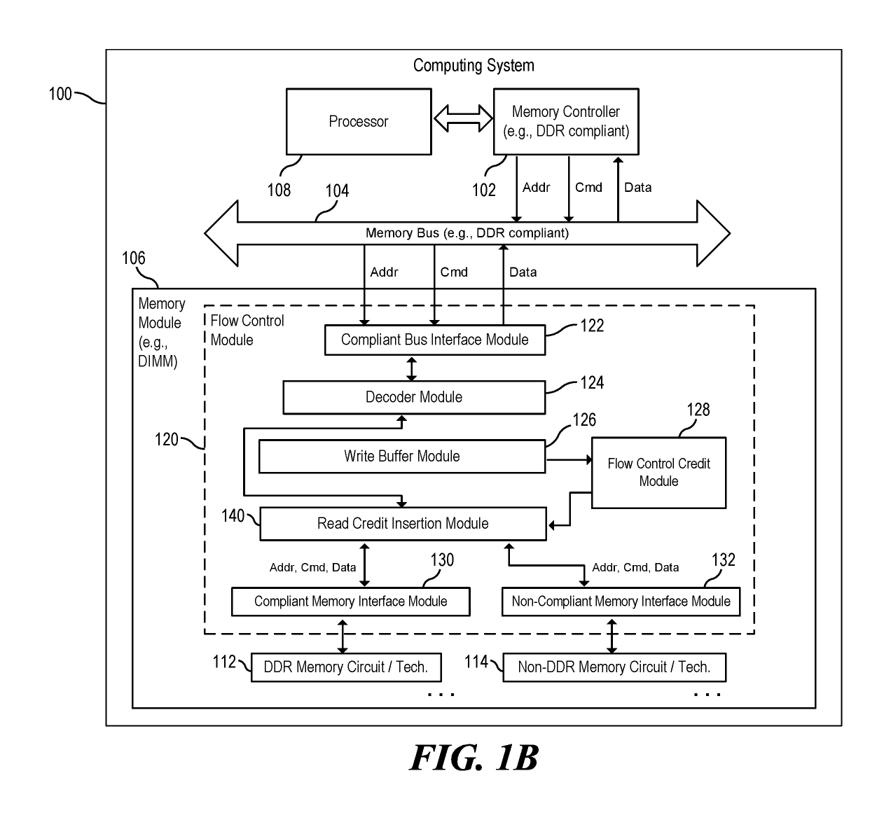

FIG. 1A is a block diagram of an example computing system 100 that implements write flow control for memory modules that include or interface with non-compliant memory technologies. Computing system 100 may be any computing system or computing device that includes a memory controller (e.g., 102) that accesses a memory module (e.g., 106), e.g., via a memory bus (e.g., 104). In the example of FIG. 1A, the data transfer standard referred to is DDR, however, it should be understood that the techniques and solutions described herein may be used with any other data transfer standard. Computing system 100 may include a memory controller 102, a memory bus 104, a memory module 106, a processor 108 and a motherboard and/or BIOS 110.

Memory controller 102 may send memory commands (e.g., write commands, read commands, etc.) to memory bus 104, which may in turn cause the memory commands to arrive at memory module 106. In some scenarios, return data may be sent from memory module 106 to memory bus 104, and in turn may arrive back at memory controller 102. In order to interface with memory bus 104, memory controller 102 may connect to memory bus 104 using, for example, a number of address (i.e., addr) wires/lines, a number of command (i.e., cmd) wires/lines and a number of data wires/lines, as shown in FIG. 1A. Memory controller 102 may send memory commands to memory module 106 and receive data from memory module 106 on behalf of some other component of computing system 100, for example, processor 108. It should be understood that, although FIG. 1A shows processor 108 interfacing with memory controller 102, it may be the case that at least one component is located between processor 108 and memory controller 102. It may also be the case that some other component (e.g., other than a processor) interfaces with memory controller 102 to communicate with memory module 106.

Memory controller 102 may be a compliant (e.g., DDR compliant) memory controller, which means that memory controller 102 may be capable of operating according to a particular data transfer standard (e.g., DDR). Thus, memory controller 102 may send data to and receive data from memory bus 104 as specified by the data transfer standard, which may specify details such as the rate (e.g., a predictable, defined and relatively fast rate) at which write commands may be sent to memory module 106. Memory bus 104 may also be compliant (e.g., DDR compliant), which means memory bus 104 may receive and transmit commands as specified by the data transfer standard. In the specific case of the a DDR data transfer standard, memory controller 102 may quickly send write commands to memory bus 104 at a predictable rate and memory bus 104 may consistently send the write commands to memory module 106 at a predictable rate. Memory controller 102 may also, at times, refrain from sending writes to memory bus 104, e.g., based on a flow control credit count, as described in more detail below. Thus, memory controller 102 may be thought of as having two write modes—a first mode where memory controller sends writes in a DDR-compliant manner, and a second mode where memory controller refrains from sending writes.

Memory module 106 may be any type of memory module (e.g., DIMM) that includes or interfaces with memory circuits and/or memory technologies (e.g., DRAM circuits). Memory module 106 may be, for example, a printed circuit board that plugs into or connect to a motherboard of the computing system 100. Memory module 106 may receive commands (e.g., write commands) from memory bus 104. In order to interface with memory bus 104, memory module 106 may connect to memory bus 104 using, for example, a number of address (i.e., addr) wires/lines, a number of command (i.e., cmd) wires/lines and a number of data wires/lines, as shown in FIG. 1A. Memory module 106 may be capable of receiving commands from memory bus 104 in a compliant manner (e.g., at a rate specified by the data transfer standard). In some examples, where flow control module 120 is a separate computer component (e.g., as described in more detail below) from memory module 106, flow control module 120 may have addr, cmd and data wires/lines that interface with memory bus 104, and memory module 106 may have connections to interface with the flow control module 120.

Memory module 106 may include or may interface with at least one compliant memory circuit or technology (e.g., DDR memory circuit/technology 112). Memory module 106 may include or may interface with at least one non-compliant memory circuit or technology (e.g., non-DDR memory circuit/technology 114). In some examples, memory module 106 may include or interface with both at least one compliant memory circuit/technology (e.g., 112) and at least one non-compliant memory circuit/technology (e.g., 114). In some examples, memory module 106 may only include or interface with at least one non-compliant memory circuit/technology (e.g., 114). In such examples, memory module 106 may not include or interface with a compliant memory circuit/technology (e.g., 112), and related components and/or modules (e.g., module 130) may be excluded.

Memory module 106 may include a flow control module 120. As can be seen in FIG. 1A, flow control module 120 is located between a compliant memory controller 102 and a non-compliant memory circuit/technology (e.g., 114). Flow control module 120 may allow non-compliant (e.g., non-volatile) memory technologies (e.g., 114) to interface with a compliant (e.g., DDR compliant) memory bus (e.g., 104) and a compliant memory controller (e.g., 102). Flow control module 120 may be implemented as electronic circuitry (i.e., a circuit). In some examples, module 120 may be implemented as hardware only (e.g., static circuitry). In other examples, module 120 may be implemented as a circuitry that is capable of being programmed or configured (e.g., firmware) or as circuitry that is capable of reading and executing instructions (e.g., circuitry with a microprocessor to execute instructions and/or software on a machine-readable storage medium). In one specific example, flow control module 120 may be an application-specific integrated circuit (ASIC) and may be attached to or mounted on memory module 106. In other examples, module 120 may be a separate computer component from memory module 106. For instance, module 120 may plug into or connect to a motherboard of computing device 100 to interface with memory bus 104, and then memory module 106 may plug into (or connect to) module 120.

Flow control module 120 may include a number of modules, for example, modules 122, 124, 126, 128, 130 and 132. Each of these modules may be, as mentioned above, electronic circuitry (e.g., hardware and/or firmware) and/or each of these modules may be instructions on a machine-readable storage medium that are executable by a microprocessor of the flow control module 120. With respect to the modules described and shown herein, it should be understood that part or all of the executable instructions and/or electronic circuitry included within one module may, in alternate embodiments, be included in a different module shown in the figures or in a different module not shown. Each of the modules shown may or may not be present in various examples, and in some examples, additional modules may be present.

Compliant bus interface module 122 may communicate with memory bus 104 (e.g., via memory module 106) according to a particular data transfer standard (e.g., DDR). For example, compliant bus interface module 122 may be capable of receiving write commands from memory bus 104 at a predictable, defined and relatively fast rate. Compliant bus interface module 122 may also receive read commands and other types of commands, according to the particular data transfer standard. Compliant bus interface module 122 may also return data (e.g., referred to as “return data”) to the memory bus 104, for example, in response to a read command. Read commands may read data from at least one compliant memory circuit/technology (e.g., 112), from at least one non-compliant memory circuit/technology (e.g., 114) and/or from flow control credit module 128. Compliant bus interface module 122 may have a number of connections to interface with memory bus 104, for example, a number of addr, cmd and data wires/lines, as shown in FIG. 1A. Compliant bus interface module 122 may feed commands (e.g., read and write commands) to decoder module 124. Compliant bus interface module 122 may also receive return data from decoder module 124.

Decoder module 124 may receive commands from compliant bus interface module 122. Decoder module 124 may route commands and/or various fields from commands to various modules of flow control module 120. For example, decoder module 124 may determine where to round particular commands (or fields) based on an address (i.e., addr) field of the command. In this respect, various modules of flow control module 120 may each be associated with a particular “address space.” As one specific example, flow control credit module 128 may be associated with a particular address. In this example, various other addresses may be associated with memory circuits/technologies (e.g., 112 and/or 114) that are on (or interface to) memory module 106. Thus, when decoder module 124 receives a command from compliant bus interface module 122, module 124 may analyze the command (e.g., the addr field) and may route the command appropriately.

Decoder module 124 may, in some instances, route less than the full command (e.g., less than all the fields of the command). For example, if decoder module receives a read command to read flow control credit module 128, module 124 may only route the addr and cmd fields to the flow control credit module. Decoder module 124 may, in some instances, pass through certain wires, lines or fields of a command without modification. For example, data lines coming into decoder module 124 (e.g., from module 122) may pass through to write buffer, for example, because the data wires/lines may not be required to decode an incoming command. Decoder module 124 may receive return data from various modules of flow control module 120, for example, from module 128. Decoder module 124 may also receive return data from at least one memory circuit/technology (e.g., 112 and/or 114), even though FIG. 1A may not show a data return path from these memory circuits/technologies back to decoder module 124. FIG. 1A may focus mainly on the functional aspects of issuing writes to the memory circuits/technologies, and thus FIG. 1A depicts only data lines routing to these memory circuits/technologies.

Write buffer module 126 may include at least one write buffer. Various descriptions herein may refer to a single write buffer of module 126, but it should be understood that these descriptions may be expanded to work with more than one write buffer. Write buffer module 126 may receive and store (e.g., in a first in first out manner) write commands from decoder module 124. The write buffer in module 126 may have a size or a capacity, which may determine how many write commands the write buffer can hold at once. The write buffer may be “full” when it is storing the same number of write commands as its size/capacity. The term “used capacity” may refer to the number of write commands that are currently being stored in the write buffer. The term “available capacity” may refer to the number of write commands that the write buffer can currently accept before it is full.

Write buffer module 126 may send stored write commands to memory circuits/technologies (e.g., 112 and/or 114), for example, via at least one interface module (e.g., 130 and/or 132). For example, interface modules 130 and/or 132 may indicate to write buffer module 126 when it is available to receive another write command. As another example, if a particular interface module (e.g., 130) is DDR compliant, write buffer module 126 may send stored write commands to the interface module as specified by a DDR data transfer standard (e.g., at a predictable, defined and relatively fast rate). In some examples, for compliant memory circuits/technologies, commands may bypass write buffer module 126, as shown in FIG. 1A. In such an example, decoder module 124 may know which commands are associated with system memory, and send such commands directly to a compliant memory interface module (e.g., 130). In other examples, memory module 106 may not include any compliant memory circuits/technologies, in which case flow control module 120 may not include any compliant memory interface modules.

Interface modules 130 and 132 may receive write commands and may transmit them to their respective memory circuits/technologies (e.g., 112, 114). Each of these memory circuits/technologies (e.g., 112, 114) may either be mounted on memory module 106 or may be external to memory module 106. If a memory circuit/technology is external to memory module 106, the respective memory interface module (e.g., 130, 132) may connect to the external memory circuit/technology via a port, connector, set of wires or the like.

Write buffer module 126 may, at various times (e.g., every cycle), communicate its available capacity to flow control credit module 128, as shown in FIG. 1A. Thus, at various times (e.g., every cycle), flow control credit module 128 may maintain a snapshot of the number of write commands that write buffer module 126 can accept. If the write buffer is full, the write buffer module may return a zero value to flow control credit module. As mentioned above, the present disclosure allows non-compliant memory technologies (e.g., 114) to interface with a compliant (e.g., DDR compliant) memory bus and a compliant memory controller. In some scenarios, non-compliant memory circuits/technologies (e.g., 114) may signal (e.g., via interface module 132) to write buffer module when it can accept additional write commands and/or when it cannot accept any more write commands. Write buffer module 126 may then use such a signal to stop sending stored write commands to such non-compliant memory circuits/technologies. In the meantime, write buffer module 126 may still receive incoming write commands (e.g., at a DDR rate). Thus, in certain scenarios, the write buffer in module 126 may begin to fill up (e.g., the available capacity may reduce).

Flow control credit module 128 may receive, at various times (e.g., every cycle), the available capacity of write buffer module. Flow control credit module 118 may translate or interpret this capacity to/as a flow control credit count, which may indicate a number of writes that may be sent. As such, flow control credit module 128 may, in some situations, be referred to as a flow control credit counter. The term “credit” (e.g., as in flow control credit) may refer to a single expendable token or point that may expire once a write command is issued (e.g., by the memory controller). At times, for ease of communication, various components and modules may send “credit counts,” which may indicate a number of credits, and thus a number of writes that may be sent. For example, if the credit count is 3, then 3 writes may be issued or sent before the credit is used up.

Flow control credit module 128 may, at various times, send flow control credits (e.g., a credit count) to memory controller 102. Flow control credits may be sent to memory controller 102 in various ways, as described in more detail below. Once memory controller 102 receives flow control credits (e.g., credit counts), it may locally keep track of a number of unused credits. In some examples, memory controller 102 may maintain a credit count. The stored credit count may indicate a number of writes that may be sent by the memory controller 102 before memory controller should stop sending writes. In some situations, if memory controller 102 has a current stored credit count value, and then receives a new credit count value (e.g., from module 128), memory controller 102 may then add the new credit count value to the current stored credit count value to update the current stored credit count value. In such a situation, the new credit count may indicate the number of credits freed since the last time the credit count was read by or sent to the memory controller. In other situations, it may be the responsibility of the memory controller to reduce the new received credit count according a number of additional writes that issued since the credit count register was read, for example, to determine the actual remaining credits at the time the memory controller receives the credits update. In such a situation, the new credit count may indicate the current number of credits in the credit count register at the time the credit register was read.

Before issuing or sending any writes to memory module 106, memory controller 102 may check the status of the flow control credit (e.g., the flow control credit count) to determine how many writes the memory controller may issue. Alternatively, or in addition, memory controller 102 may check the status of the flow control credit at various other times. Each time memory controller 102 issues a write, it may “consume” a flow control credit, and the stored credit count may reduce by one. If at some time, the flow control credit count is zero, and if no other flow control credits are available to consume, memory controller 102 may refrain from issuing or sending any write commands to memory module 106. Then, at a later time, memory controller may receive a new credit count, which may indicate that capacity in the write buffer of module 126 has freed up, and then memory controller 102 may resume issuing or sending write commands.

Memory controller 102 may need to be designed and/or configured to request, receive, interpret and/or act upon these flow control credits. However, it should be understood that an interface of the memory controller 102 may still comply with a particular data transfer standard (e.g., DDR). Additionally, as indicated above, when memory controller 102 does send write commands (e.g., when it has flow control credits to consume), it may send the commands according to a particular data transfer standard (e.g., DDR). Thus, even though memory controller 102 may need to be altered when compared to a memory controller that does not implement flow control credits, an altered memory controller may still be able to interface with all other computer components of computing system 100 that comply with the data transfer standard. For example, a motherboard, including a socket for a DIMM memory module may not need to be altered (e.g., they may remain compliant). As one specific scenario, in some systems, the memory controller is part of a central processor (e.g., 108), and thus, an existing processor may simply be swapped out with a processor that includes an altered memory controller 102, and then the computing system may be ready to implement flow controller credits (e.g., assuming that a flow control module 120 is used).

As one example of how flow control credits may be sent to memory controller 102, flow control credit module 128 may include a credits register that may be read by memory controller 102. The credits register may have an address, and memory controller 102 may issue a read to that address, and in response, may receive return data, in a similar manner as if memory controller 102 had issued a read command to a memory circuit. When memory module 106 receives a read command directed to the credits register, decoder module 124 may route the read to flow control credit module 128. Decoder module may then receive the credits (e.g., a credit count) from the credits register as return data, and may return this data to memory controller 102. Because flow control credits may be requested and received by the memory controller via the same communication wires/lines (e.g., addr, cmd, data) that the memory bus uses to read and write from and to memory circuits, the memory controller may become aware of when it may issue write commands (e.g., without overrunning write buffer 126) or when it may not issue write commands, without the need for an extra signaling wire/line. This may provide benefits over some approaches that include an extra wire or line that allows a DIMM to signal when the DIMM is not ready to accept another write.

Memory controller 102 may read the credits register at various times to receive an update on the available capacity of the write buffer in module 126. For example, before issuing any writes, if memory controller does not have any stored and unused credits, memory controller 102 may read the credits register. Memory controller 102 may also read the credits register when there are available cycles on the interface before it is out of credits. Memory controller 102 may read the credits register at various other times as well.

As another example of how flow control credits may be sent to memory controller 102, memory module 106 may include an SPD circuit 134 that may store an initial credit count. In some examples, SPD circuit 134 may be an SPD ROM or other type of SPD component. In general, a SPD (serial presence detect) component of a memory module may be used when a computer (e.g., computing system 100) is turned on or restarted. When the computer is turned on or restarted, it may perform a power-on self-test to detect, for example, what memory is present in the system, and what timings to use to access the memory. Such information may be used to configure the memory controller. A SPD component may include a ROM (read only memory) or other type of memory that stores various pieces of information that may be access by the computer during a power-on self-test. In some examples, such an SPD component may store an initial credit count. SPD circuit 134 may store and provide this initial credit count.

An initial credit count provided by SPD circuit 134 may make its way to memory controller 102 in various ways. For example, the motherboard and/or BIOS 110 of computing system 100 may read SPD circuit 134 (e.g., an SPD ROM) of memory module 106. SPD circuit 134 may be accessed using an I²C interface, SMBus interface or some other type of interface for accessing SPD components. An I²C interface may connect an SPD component to a motherboard, and may include just two pins, e.g., for a clock signal and a data signal. Other interfaces may be used to access SPD circuit 134 as well. Once motherboard and/or BIOS 110 receive this initial credit count information, they may communicate it to memory controller 102 to configure the memory controller. Motherboard and/or BIOS 110 may communicate this initial credit count directly to memory controller 102 or via a central processor (e.g., 108).

In some examples, SPD circuit 134 of memory module 106 may only be used to communicate an initial credit count to memory controller 102. Thus, for example, when computing system 100 is powered on, memory controller may receive this initial credit count. Then, the memory controller may request and/or receive subsequent credit count updates via at least one of the other manners described herein (e.g., by reading a register in flow control credit module 128, as described above, and/or by receiving an extra read cycle, as described below).

FIG. 1B is a block diagram of example computing system 100 that implements write flow control for memory modules that include or interface with non-compliant memory technologies. Computing system 100 may be the same computing system 100 depicted in FIG. 1A. Whereas FIG. 1A depicted various features that were associated with issuing write commands, FIG. 1B depicts various features that are associated with issuing read commands, particularly, receiving flow control credits (e.g., credit counts) via an extra read cycle, as described in more detail below. It will be seen, by comparing FIGS. 1A and 1B, that various modules and/or components are shared between the two figures. However, for ease of description, some modules and/or components are shown in FIG. 1A and not in 1B, and vice versa. For example, computing system 100 may include a read credit insertion module 140. It should be understood that some example computing systems may include any combination of the modules and/or components shown in either FIGS. 1A and/or 1B. Some example computing systems may include all the components shown in either FIGS. 1A and/or 1B.

As another example of how flow control credits may be sent to memory controller 102, read credit insertion module 140 may extend the return data phase of read transactions by at least one extra cycle. In that extra cycle, module 140 may cause a current credit count to be returned to the memory controller as though the credit count was return data.

Read credit insertion module 140 may receive, at various times (e.g., every cycle), a current credit count from flow control credit module 128, as shown in FIG. 1B. Read credit insertion module 140 may receive read commands issued by memory controller 102. In some examples, module 140 may pass through (e.g., unaltered) read commands to at least one compliant memory circuit/technology (e.g., 112) and/or at least one non-compliant memory circuit/technology (e.g., 114). Read credit insertion module 140 may then receive return data from the memory circuits/technologies. In various situations, a response to a read command may be returned to memory controller in multiple cycles, for example, because the amount of return data is too large to fit within the bits of the data wires/lines. Read credit insertion module 140 may cause responses to read commands to include at least one additional cycle, e.g., after the last cycle of return data from a memory circuit. Read credit insertion module 140 may insert the last received flow control credit count into this additional cycle, and may format it to be sent as return data back to memory controller 102.

Memory controller 102 and module 140 may both be aware of and follow a routine, algorithm or the like that determines when flow control credits are returned in an extra data return cycle such that the credits are expected at the memory controller, and such that the memory bus may be scheduled to be free to carry the credits across the compliant bus interface. Memory controller 102 may need to be designed and/or configured to know how to handle an extra read cycle that may include a credit count. However, as indicated above, an interface of the memory controller 102 may still comply with a particular data transfer standard (e.g., DDR).

In some examples, read credit insertion module 140 may conditionally (e.g., only sometimes) cause responses to read commands to include an additional cycle. For example, read credit insertion module 140 (and/or some other module of flow control module 120 or memory module 106) may track how many write commands have been received by memory module 106 since that last time the credit count was requested/read/sent. In this example, if a defined number of writes have been received, credit insertion module 140 may cause an extra read cycle to be inserted, and a current credit count may be sent. Thus, it may be seen that flow control module 120 may implement (e.g., concurrently) various ways of sending credit counts to memory controller 102. For example, during idle cycles, memory controller 102 may explicitly read flow control credit module 128, and then during busier times, if several writes have issued since memory controller 102 has been able to read flow control credit module 128, read credit insertion module 140 may insert the current credit count as an extra read cycle. As another example, if the memory controller issues several writes before it issues a read, the memory controller may need to explicitly read flown control credit module 128 because a read cycle may not be available to receive the flow control credit count. Various other circumstances may be contemplated where these ways of returning the flow control credit may work together.

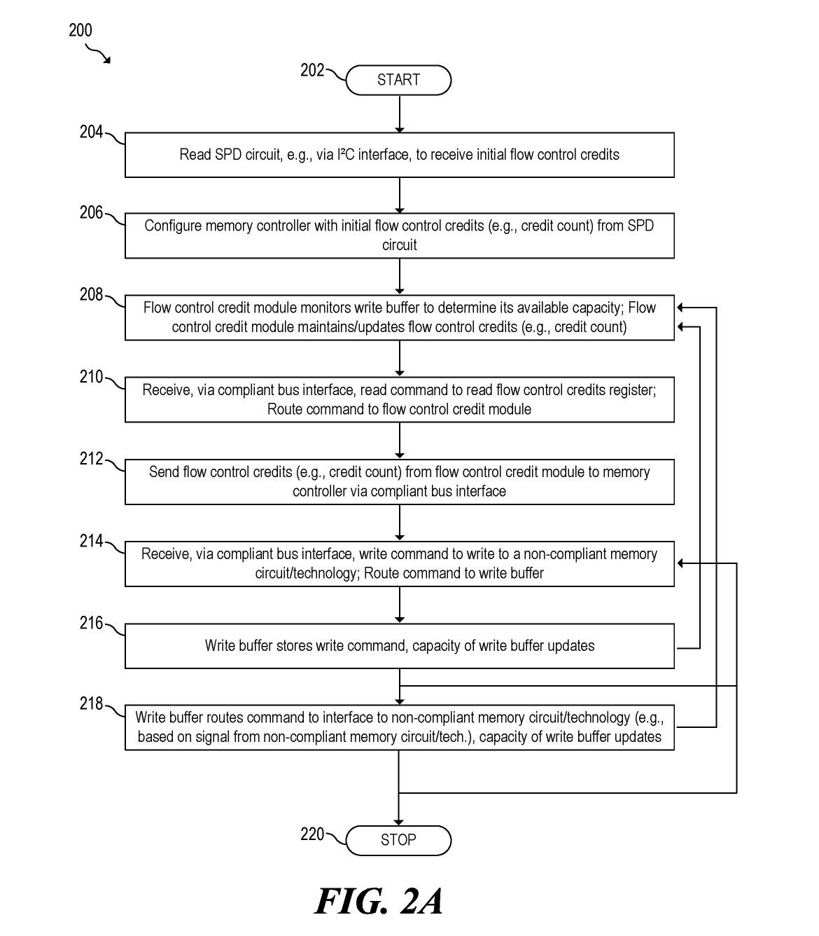

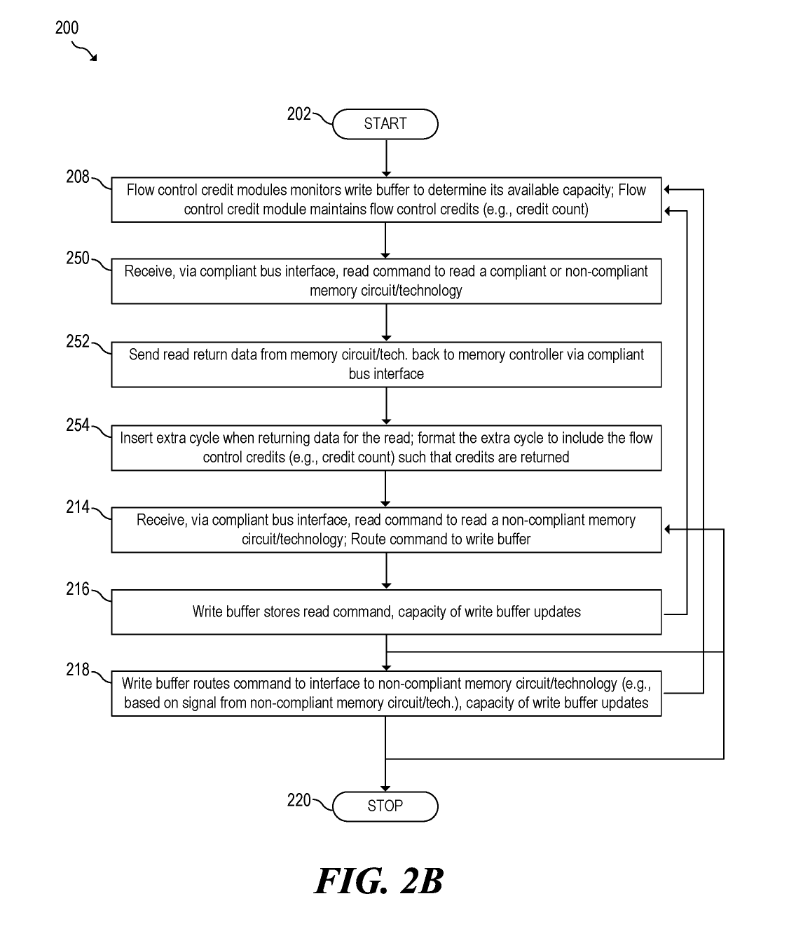

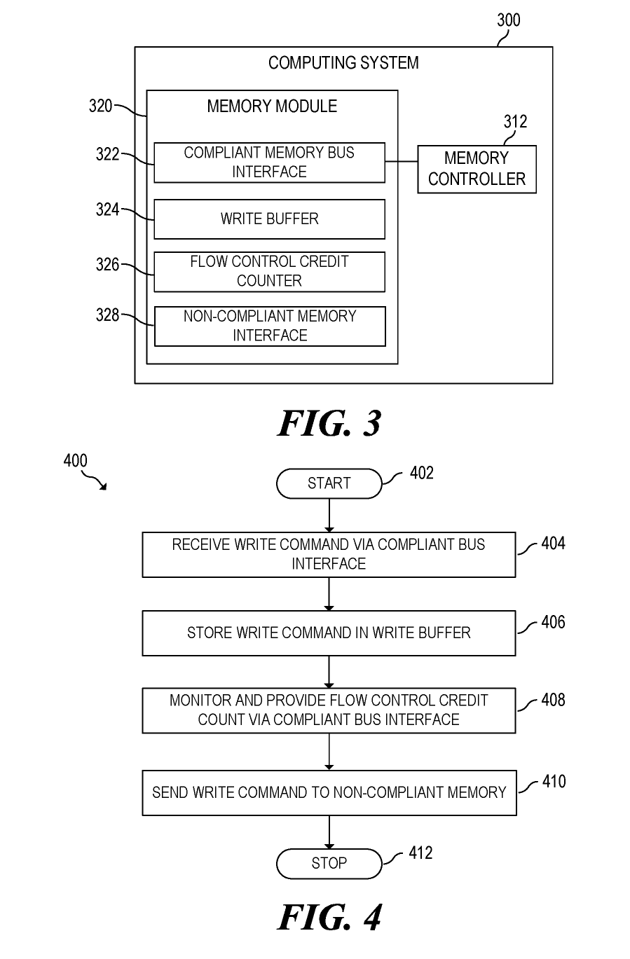

FIGS. 2A and 2B depict a flowchart of an example method 200 for write flow control for memory modules that include or interface with non-compliant memory technologies. It will be seen, by comparing FIGS. 2A and 2B, that various steps are shared between the two figures. However, for ease of description, some steps are shown in FIG. 2A and not in 2B, and vice versa. For example, FIG. 2B may not show steps 204, 206, 210 and 212, but FIG. 2B may show steps 250, 252 and 254. It should be understood that in some examples, method 200 may include any combination of the steps shown in either FIGS. 2A and/or 2B. In some examples, method 200 may include all the steps shown in either FIGS. 2A and/or 2B. In alternate embodiments of the present disclosure, one or more steps of method 200 may be executed substantially concurrently or in a different order than shown in FIGS. 2A and 2B. In alternate embodiments of the present disclosure, method 200 may include more or less steps than are shown in FIGS. 2A and 2B. In some embodiments, one or more of the steps of method 200 may, at certain times, be ongoing and/or may repeat. Method 200 may be executed by a flow control credit module (e.g., 120 of FIG. 1A) or any other suitable electronic circuitry, for example, circuitry on memory module 320 of FIG. 3. Method 200 may be implemented in form of electronic circuitry and/or in the form of executable instructions stored on a machine-readable storage medium, e.g., a machine-readable storage medium disposed in flow control credit module 120.

Referring to FIG. 2A, method 200 may start at step 202 and continue to step 204, where a SPD circuit (e.g., 134) may be read, e.g., via an I²C interface, to receive initial flow control credits. At step 206, a memory controller (e.g., 102) may be configured with the initial flow control credits (e.g., credit count) from the SPD circuit. As discussed in more detail above, steps 204 and 206 may be an initialization phase that may execute, for example, when a computing system starts up or restarts. At step 208, a flow control credit module (e.g., 128) may monitor a write buffer (e.g., inside write buffer module 126) to determine the available capacity of the write buffer. Also at step 208, the flow control credit module may maintain and/or update flow control credits (e.g., credit count). At step 210, flow control module 120 may receive, via a compliant bus interface (e.g., module 122), a read command to read a flow control register (e.g., inside flow control credit module 128). Also at step 210, flow control module 120 (e.g., via decoder module 124) may route the command to the flow control credit module. At step 212, the flow control module may send flow control credits (e.g., credit count) from the flow control credit module to the memory controller via the compliant bus interface.

At step 214, flow control module 120 may receive, via a compliant bus interface (e.g., module 122), a write command to write to a non-compliant memory circuit/technology (e.g., 114). Also at step 214, flow control module 120 (e.g., via decoder module 124) may route the command to the write buffer. At step 216, the write buffer may store the incoming write command, and the capacity of the write buffer may update (decrease). At this point, as just one example of how method 200 may have steps that are ongoing and/or repeat, method 200 may return to step 208, and the updated write buffer may be monitored by the flow control credit module. Also at this point, once the write buffer stores an incoming write, if the write buffer has available capacity, it may accept another write command, as indicated by the arrow returning to step 214. At step 218, the write buffer may route a write command (e.g., in a first in first out manner) to an interface (e.g., 132) to the non-compliant memory circuit/technology. As one example, the non-compliant memory circuit/technology may use a signal, line or wire to indicate to the write buffer when it can or cannot accept another write command. Also at step 218, the write buffer may update (increase) its capacity to account for removing a write command. At this point, as just one example of how method 200 may have steps that are ongoing and/or repeat, method 200 may return to step 208, and the updated write buffer may be monitored by the flow control credit module. Also at this point, the write buffer may accept another write command, as indicated by the arrow returning to step 214. Method 200 may eventually continue to step 220, where method 200 may stop.

Referring to FIG. 2B, steps 202, 208, 214, 216, 218 and 220 may be the same steps as shown in FIG. 2A. Additionally, method 200 may include steps 250, 252 and 254. At step 250, flow control module 120 may receive, via the compliant bus interface (e.g., module 122), a read command to read a compliant or non-compliant memory circuit/technology (e.g., 112 or 114). At step 252, flow control module 120 may send read return data from the memory circuit/technology back to the memory controller via the compliant bus interface. The response to the read command may pass through a read credit insertion module (e.g., 140), for example. At step 254, flow control module 120 (e.g., via module 140) may insert an extra cycle when returning data for the read. Module 140 may format the extra cycle to include the flow control credits (e.g., credit count) such that the current flow control credits are returned to the memory controller. Memory controller 102 and module 140 may both be aware of and follow the routine, algorithm or the like that determines when flow control credits are returned in an extra data return cycle such that the credits are expected at the memory controller, and such that the memory bus may be scheduled to be free to carry the credits across the compliant bus interface. Method 200 may eventually continue to step 220, where method 200 may stop.

FIG. 3 is a block diagram of an example computing system 300 for write flow control for memory modules that include or interface with non-compliant memory technologies. Computing system 300 may be any computing system or computing device that includes a memory controller (e.g., 312) that accesses a memory module (e.g., 320), e.g., via a memory bus. More details regarding an example computing system may be described above, for example, with respect to computing system 100 of FIG. 1A. In the embodiment of FIG. 3, computing system 300 includes a memory controller 312 and a memory module 320. Memory controller 312 may be similar to memory controller 102 of FIG. 1A and memory module 320 may be similar to memory module 106, for example.

Memory module 320 may include a number of components 322, 324, 326 and 328. Each component may be implemented in form of electronic circuitry and/or in the form of executable instructions stored on a machine-readable storage medium, e.g., a machine-readable storage medium disposed in memory module 320. Such a machine-readable storage medium may be any electronic, magnetic, optical, or other physical storage device that stores executable instructions. Thus, such a machine-readable storage medium may be, for example, Random Access Memory (RAM), an Electrically-Erasable Programmable Read-Only Memory (EEPROM), and the like. In the case of components 322, 324, 326 and 328 being implemented as executable instructions, memory module 320 may include any kind of microprocessor suitable for retrieval and execution of instructions stored in the machine-readable storage medium. Such a processor may fetch, decode, and execute instructions (e.g., components 322, 324, 326, 328) to, among other things, implement flow control for memory modules that include or interface with non-compliant memory technologies. With respect to the component boxes (e.g., 322, 324, 326, 328) shown in FIG. 3, it should be understood that part or all of the executable instructions and/or circuitry included within one box may, in alternate embodiments, be included in a different box shown in the figures or in a different box not shown.

Compliant memory bus interface 322 may communicate with memory controller 312 via a memory bus. Interface 322, memory controller 312 and the memory bus may each be compliant with a particular data transfer standard (e.g., DDR). Write buffer 324 may receive write commands from the interface to the memory bus. The write buffer may cause the received write commands to be written to a non-compliant memory circuit or technology that does not comply with the data transfer standard. Flow control credit counter 326 may monitor the capacity of the write buffer. The flow control credit counter may maintain a credit count that indicates the number of write commands that the write buffer can accept. The flow control credit counter may provide the credit count to the memory controller via the interface to the memory bus and the memory bus. Non-compliant memory interface 328 may communicate with the non-compliant memory circuit or technology in a manner that does not comply with the data transfer standard.

FIG. 4 is a flowchart of an example method 400 for write flow control for memory modules that include or interface with non-compliant memory technologies. Method 400 may be executed by a memory module (e.g., 320 of FIG. 3) or any other suitable electronic circuitry, for example, flow control module 120 of FIG. 1A. Method 400 may be implemented in form of electronic circuitry and/or in the form of executable instructions stored on a machine-readable storage medium, e.g., a machine-readable storage medium disposed in memory module 320. In alternate embodiments of the present disclosure, one or more steps of method 400 may be executed substantially concurrently or in a different order than shown in FIG. 4. In alternate embodiments of the present disclosure, method 400 may include more or less steps than are shown in FIG. 4. In some embodiments, one or more of the steps of method 400 may, at certain times, be ongoing and/or may repeat.

Method 400 may start at step 402 and continue to step 404, where memory module 320 may receive a write command via an interface (e.g., 322) to a memory bus that complies with a first data transfer standard, wherein the memory bus communicates with a memory controller (e.g., 312). At step 406, memory module 320 may store the write command in a write buffer (e.g., 324) and may update a capacity of the write buffer. At step 408, memory module 320 may monitor (e.g., via flow control credit counter 326) the capacity of the write buffer to maintain a flow control credit count that indicates the number of write commands that the write buffer can accept. Flow control credit counter 326 may provide the flow control credit count to the memory controller via the interface to the memory bus and the memory bus. At step 410, memory module may cause the write command to be written from the write buffer to (e.g., via interface 328) a non-compliant memory circuit or technology that does not comply with the first data transfer standard. Method 400 may eventually continue to step 412, where method 400 may stop.

1. A memory module for write flow control, the memory module comprising:
an interface to a memory bus that complies with a data transfer standard that specifies cycle or timing information to send data, wherein the memory bus communicates with a memory controller;
an interface to a non-compliant memory technology that does not comply with the data transfer standard;
a write buffer to receive write commands from the interface to the memory bus, wherein the write buffer causes the received write commands to be transmitted to the non-compliant memory technology using a communication protocol that does not comply with the data transfer standard; and
a flow control credit counter to monitor the capacity of the write buffer, wherein the flow control credit counter provides a credit count to the memory controller that indicates the number of write commands that the write buffer can accept.

2. The memory module of claim 1, wherein the data transfer standard is a double data rate (DDR) standard.

3. The memory module of claim 2, wherein the non-compliant memory technology is a non-volatile memory technology and the communication protocol is used to communicate with non-volatile memories.

4. The memory module of claim 1, wherein the flow control credit counter includes a register that can be read from by the memory bus by providing an address to the interface to the memory bus.

5. The memory module of claim 1, further comprising a serial presence detect (SPD) circuit, wherein the SPD circuit provides an initial credit count to initialize the memory controller.

6. The memory module of claim 1, wherein the credit count is provided to the memory bus via the same communication wires that the memory bus uses to read and write from and to memory circuits and/or technologies of the memory module.

7. The memory module of claim 1, wherein the credit count is provided to the memory bus without using additional communication wires beyond what the memory bus uses to read and write from and to memory circuits and/or technologies of the memory module.

8. The memory module of claim 1, wherein the credit count is provided to the memory bus by an extra return data cycle in response to a read command sent by the memory bus to the memory module.

9. A method for write flow control executed in a memory module, the method comprising:
receiving a write command via an interface to a memory bus that complies with a data transfer standard, wherein the memory bus communicates with a memory controller;
storing the write command in a write buffer and updating a capacity of the write buffer;
monitoring the capacity of the write buffer to maintain a flow control credit count that indicates the number of write commands that the write buffer can accept, and providing the flow control credit count to the memory controller via the interface to the memory bus and the memory bus; and
causing the write command to be written from the write buffer to a non-compliant memory technology that does not comply with the data transfer standard using a communication protocol that does not comply with the data transfer standard.

10. The method of claim 9, wherein flow control credit count is used by the memory controller to determine whether the memory controller can issue write commands to the memory module.

11. The method of claim 9, further comprising receiving a read command via the interface to a memory bus to read a register that stores a current value of the flow control credit count, wherein providing the flow control credit count to the memory controller includes returning the flow control credit count as return data in response to the read command.

12. The method of claim 9, further comprising:
receiving a read command via the interface to a memory bus to read a memory technology included on or in communication with the memory module; and
when returning data to the memory bus in response to the read command, inserting an extra return data cycle that includes the flow control credit count.

13. A computing system, comprising:
a memory controller that complies with a double data rate (DDR) data transfer standard, and a memory bus coupled to the memory controller that complies with the DDR data transfer standard;
a memory module that includes or interfaces with a non-compliant memory technology that does not comply with the DDR data transfer standard; and
a flow control circuit, the flow control circuit including:
an interface to the memory bus, wherein the interface complies with the DDR data transfer standard, and an interface to the non-compliant memory technology;
a write buffer to receive write commands from the interface to the memory bus, wherein the write buffer causes the received write commands to be written to the non-compliant memory technology; and
a flow control credit counter to monitor the capacity of the write buffer, wherein the flow control credit counter provides, to the memory controller, a credit count that indicates the number of write commands that the write buffer can accept.

14. The computing system of claim 13, wherein the non-compliant memory technology is a non-volatile memory technology.

15. The computing system of claim 13, wherein the credit count is provided to the memory bus via the same communication wires that the memory bus uses to read and write from and to memory circuits and/or technologies of the memory module.
